(19) United States
(12) Patent Application Publication
(10) Pub. No.: US 2025/0246473 A1
(43) Pub. Date: Jul. 31, 2025

(54) ELECTROSTATIC CHUCK

(71) Applicant: TOTO LTD., Fukuoka (JP)

(72) Inventors: Yuki SASAKI, Fukuoka (JP); Jun SHIRAISHI, Fukuoka (JP); Yutaka MOMIYAMA, Fukuoka (JP); Ikuo ITAKURA, Fukuoka (JP); Hitoshi SASAKI, Fukuoka (JP)

(21) Appl. No.: 19/035,450

(22) Filed: Jan. 23, 2025

(30) Foreign Application Priority Data
Jan. 25, 2024 (JP) 2024-009227

(51) Int. Cl. H01L 21/683; H01J 37/32

(52) U.S. Cl. CPC H01L 21/6833; H01J 37/32724; H01J 2237/002; H01J 2237/2007; H01J 2237/334

(57) ABSTRACT

An electrostatic chuck includes a dielectric substrate including a surface serving as a placement surface, and a base plate which is joined to the dielectric substrate and which has formed therein a coolant flow path through which a coolant flows. In top view, the base plate includes a first part that is a part overlapped with an edge on an outer circumferential side of the surface, and a second part P2 that is a part on the further outer circumferential side relative to the first part P1, and the coolant flow path is formed in each of the first part P1 and the second part. The coolant flow path is formed in a manner that a cooling performance for the first part is set to be higher than a cooling performance for the second part.

### CROSS-REFERENCE TO RELATED APPLICATION

This application is based upon and claims the benefit of priority from Japanese Patent Application No. 2024-009227 filed on Jan. 25, 2024, the entire contents of which are incorporated herein by reference.

### FIELD

The present invention relates to an electrostatic chuck.

### BACKGROUND

For example, in a semiconductor manufacturing apparatus such as an etching apparatus, an electrostatic chuck is provided as an apparatus configured to attract and hold a wafer such as a silicon wafer to be processed. The electrostatic chuck includes a dielectric substrate to which an attraction electrode is provided and a base plate which supports the dielectric substrate, and has a configuration in which these are joined to each other. When a voltage is applied to the attraction electrode, an electrostatic force is generated, and the wafer placed on the dielectric substrate is attracted and held.

During a process such as etching, a temperature of the wafer is to be maintained at an appropriate temperature. For this reason, as described in Japanese Patent Laid-Open No. 2011-151055, a coolant flow path through which a coolant flows is formed inside the base plate. Heat from the wafer is transferred to the coolant via the dielectric substrate and the base plate, and then the heat is exhausted to the outside together with the coolant.

### SUMMARY

During the process such as etching, a temperature in an outer circumferential part, in particular, in the wafer tends to increase. An optimal routing of the coolant flow path in the base plate has been studied for such a purpose that the above-mentioned temperature increase in the outer circumferential part is to be reduced and an in-plane temperature distribution of the wafer is set to be as uniform as possible. It is noted however that in related art, a main focus has been on a routing of the coolant flow path in a range overlapped with the wafer in top view, and there is a room for a further improvement with regard to a routing of the coolant flow path in other parts.

The present invention has been made in view of the above-mentioned issue and is aimed to provide an electrostatic chuck in which an in-plane temperature distribution of a wafer during a process can be set as a more uniform distribution than before.

To address the above-mentioned issue, an electrostatic chuck according to an aspect of the present invention includes a dielectric substrate including a placement surface on which an object to be attracted is placed, and a base plate which is joined to the dielectric substrate and which has formed therein a coolant flow path through which a coolant flows. When viewed from a direction perpendicular to the placement surface, the base plate includes a first part serving as a part overlapped with an outer circumferential edge of the placement surface, and a second part serving as a part on a further outer circumferential side relative to the first part, and the coolant flow path is formed in each of the first part and the second part. The coolant flow path is formed in a manner that a cooling performance for the first part is set to be higher than a cooling performance for the second part.

In the electrostatic chuck with the above-described configuration, the coolant flow path is formed in not only a part immediately below the wafer in the base plate but also up to the second part located on the outer side relative to the above-described part. By forming the coolant flow path in such a range, a temperature increase in an outer circumferential part of the wafer can be reduced. In the electrostatic chuck with the above-described configuration, the coolant flow path is formed in a manner that the cooling performance for the first part is set to be higher than the cooling performance for the second part. With the cooling performance varied between the first part and the second part, while the temperature increase in the outer circumferential part of the wafer is sufficiently reduced, it is possible to avoid a situation where a member (for example, a focus ring or the like) arranged on the further outer side relative to the outer circumferential part of the wafer is cooled down more than necessary. According to this, an in-plane temperature distribution of the wafer during a process can be set as a more uniform distribution than before.

According to the aspect of the present invention, it is possible to provide the electrostatic chuck in which the in-plane temperature distribution of the wafer during the process can be set as the more uniform distribution than before.

### BRIEF DESCRIPTION OF THE DRAWINGS

FIG. 1 is a cross sectional view schematically illustrating a configuration of an electrostatic chuck according to a first embodiment;

FIG. 2 schematically illustrates a configuration of a coolant flow path formed in a base plate of the first embodiment;

FIG. 3 is a cross sectional view schematically illustrating a configuration of the electrostatic chuck according to a second embodiment; and

FIG. 4 schematically illustrates a configuration of the coolant flow path formed in the base plate of a third embodiment.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be attracted is, for example, a silicon wafer. The electrostatic chuck 10 may be used in an apparatus other than the semiconductor manufacturing apparatus.

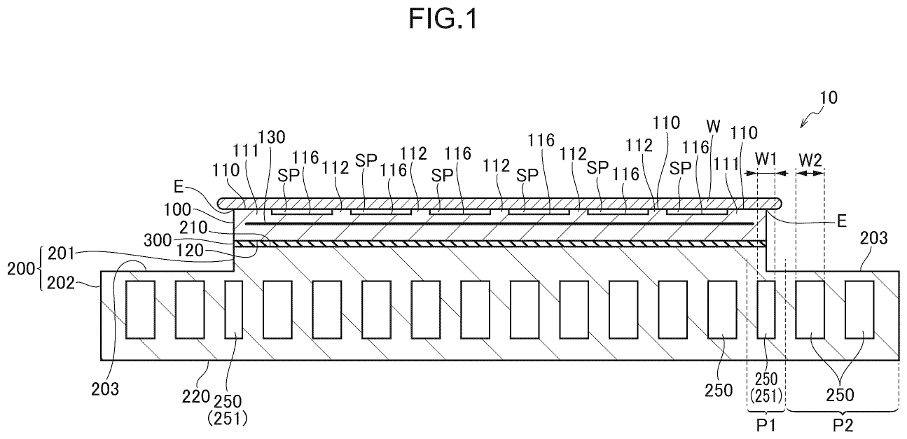

FIG. 1 is a cross sectional view schematically illustrating a configuration of the electrostatic chuck 10 in a state in which the wafer W is attracted and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus. A diameter of the dielectric substrate 100 is, for example, 290 to 300 mm. A thickness of the dielectric substrate 100 is, for example, 0.5 to 3.0 mm.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via a joining layer 300. A perspective in a case where the electrostatic chuck 10 is viewed from the surface 110 side along a direction perpendicular to the surface 110 will also be hereinafter expressed as “top view”.

An attraction electrode 130 is embedded inside the dielectric substrate 100. The attraction electrode 130 is a thin planar layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from an outside via a feed line which is not illustrated in the drawing, an electrostatic force is generated between the surface 110 and the wafer W, and according to this, the wafer W is attracted and held. As a configuration of the above-described feed line, various configurations in related art can be adopted. The single attraction electrode 130 may be provided as so-called a “monopolar” electrode as in the present embodiment, but may also include two attraction electrodes as so-called “bipolar” electrodes. A depth of a position where the attraction electrode 130 is arranged, that is, a distance from a bottom 116 which will be described below to the attraction electrode 130 is, for example, 0.1 to 0.5 mm.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via a gas hole which is not illustrated in the drawing. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. An upper end of the seal ring 111 becomes a part of the surface 110 and abuts against the wafer W. It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. An upper end of each of the dots 112 becomes a part of the surface 110 and abuts against the wafer W. By providing the plurality of thus configured dots 112, warping of the wafer W is reduced.

The base plate 200 is a substantially disk-shaped member which supports the dielectric substrate 100. The base plate 200 is made of, for example, a metallic material such as aluminum. The base plate 200 is joined to the surface 120 of the dielectric substrate 100 via the joining layer 300. A surface 210 on the upper side in FIG. 1 in the base plate 200 serves as a “surface to be joined” which is joined to the dielectric substrate 100 via the joining layer 300.

The joining layer 300 is a layer provided between the dielectric substrate 100 and the base plate 200 to join those components. The joining layer 300 is obtained by causing an adhesive made of an insulating material to be cured. According to the present embodiment, a silicone adhesive is used as the above-described adhesive. It is noted however that the joining layer 300 may be obtained by causing an adhesive made of other types to be cured. In any case, in order that a thermal resistance between the dielectric substrate 100 and the base plate 200 is reduced, a material with a highest possible thermal conductivity is preferably used as the material of the joining layer 300.

An insulating film may be formed on a surface of the base plate 200. As the insulating film, for example, an alumina film formed by thermal splaying can be used. When the surface of the base plate 200 is covered by the insulating film, it is possible to increase a withstand voltage of the base plate 200. A thickness of the insulating film is, for example, equal to or less than 1 mm.

The base plate 200 includes a support section 201 and a flange section 202. The support section 201 is an upper part in FIG. 1 of the base plate 200 and is a substantially cylindrical part which directly supports the dielectric substrate 100 from below. A diameter of the support section 201, that is, a diameter of the surface 210 may be the same as the diameter of the dielectric substrate 100 but may be slightly smaller than the diameter of the dielectric substrate 100. The diameter of the support section 201 is, for example, 290 to 300 mm. A thickness of the support section 201, that is, an amount of protrusion of the support section 201 which faces upwards in FIG. 1 (amount of protrusion from the flange section 202) is, for example, 3 to 15 mm.

The flange section 202 is a lower part in FIG. 1 of the base plate 200. A shape of the flange section 202 is a substantially cylindrical shape, and a central axis of the flange section 202 matches a central axis of the support section 201. A diameter of the flange section 202 is larger than the diameter of the support section 201. An amount of protrusion of the flange section 202 from a lateral surface of the support section 201 (that is, an amount of protrusion in a radial direction) is, for example, 20 to 30 mm. A thickness of the flange section 202 is, for example, 25 to 40 mm. An entire thickness of the base plate 200 including the support section 201 and the flange section 202 is, for example, 30 to 40 mm.

When a process on the wafer W is to be performed in the semiconductor manufacturing apparatus, a focus ring which is not illustrated in the drawing is installed on an upper surface 203 of the flange section 202. The focus ring is an annular and plate-like member made of an insulating material such as quartz, for example, and is installed for a purpose of regulating a distribution of plasma during the process. A state is established in which almost the whole of the dielectric substrate 100 and the support section 201 is surrounded by the focus ring from an outer circumferential side.

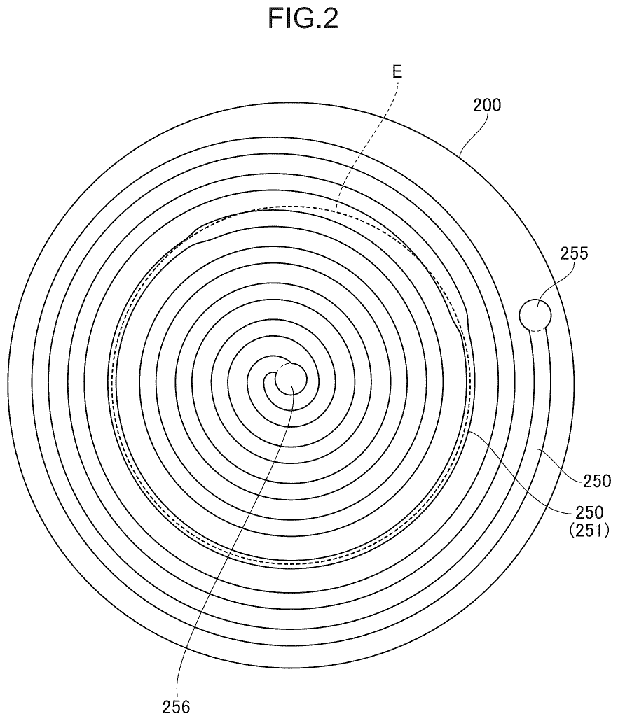

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings 255 and 256 (which are not illustrated in FIG. 1; see FIG. 2) formed in a surface 220 opposite to the surface 210 in the base plate 200.

For convenience of description, an edge on the outer circumferential side in the surface 110 serving as the placement surface will also be hereinafter referred to as an “edge E”. The edge E becomes a circular ridge in top view but may become a ridge with a shape different from the circular shape in some part (for example, an orientation flat part).

A part overlapped with the edge E in top view in the base plate 200 will also be hereinafter referred to as a “first part P1”. The first part P1 is, for example, a part having a predetermined width so as to include an entirety of the edge E in top view, but a method of determining the width is not particularly limited.

A part on a further outer circumferential side relative to the first part P1 in top view in the base plate 200 will also be hereinafter referred to as a “second part P2”. The second part P2 is a part adjacent to the first part P1 from the outer circumferential side in the base plate 200 and refers to an entirety of the part located on the further outer circumferential side relative to the first part P1.

During the process such as etching, it has been found out that a temperature in the part on the outer circumferential side, in particular, in the wafer W tends to increase. In the electrostatic chuck 10 of the present embodiment, various improvements as will be described below have been made such that the above-described local temperature increase is reduced, and an in-plane temperature distribution of the wafer W during the process is set to be as uniform as possible.

As illustrated in FIG. 1, the coolant flow path 250 is routed not only in the first part P1 and a part on an inner side relative to the first part P1 in the base plate 200 but also in the second part P2 on an outer side relative to the first part P1. That is, the coolant flow path 250 is formed across the second part P2 located on the outer side relative to the wafer W and the part immediately below the support section 201 (that is, the first part P1 and the like). With the coolant flowing through the coolant flow path 250 in the second part P2, the focus ring which is not illustrated in the drawing and which is located immediately above the second part P2 is cooled down, and an outer circumferential part of the wafer W is also cooled down via the focus ring.

According to the present embodiment, the diameter of the flange section 202 becomes relatively large, and as a result of this, the second part P2 also becomes large. By setting the second part P2 to be large and forming the coolant flow path 250 across almost the whole of the second part P2 to cause the coolant to circulate through such a coolant flow path, it becomes possible to reduce the temperature increase in the outer circumferential part of the wafer W.

FIG. 2 schematically depicts the configuration of the coolant flow path 250 formed inside the base plate 200 in top view. As described above, the openings 255 and 256 are provided in the surface 220 of the base plate 200. The coolant flow path 250 is formed along such a route that connects the opening 255 and the opening 256. For example, the opening 255 is used as an inlet for the coolant, and the opening 256 is used as an outlet for the coolant. A circular dotted line illustrated in FIG. 2 represents the edge E on the outer circumferential side of the surface 110 serving as the placement surface.

According to the present embodiment, the opening 255 is formed in a position close to the edge on the outer circumferential side in the base plate 200, and the opening 256 is formed in a central position of the base plate 200. The coolant flow path 250 connects the opening 255 and the opening 256 in a spiral manner and is routed via such a path as to pass through almost the whole of the base plate 200.

A part routed in the first part P1 (that is, the part immediately below the edge E) in the coolant flow path 250 will also be hereinafter expressed as a “coolant flow path 251”. As illustrated in FIG. 2, the coolant flow path 251 is routed so as to extend in an arc-like manner along the edge E in top view.

As illustrated in FIG. 1, a width W1 of the coolant flow path 251 in the first part P1 is narrower than a width W2 of the coolant flow path 250 in the second part P2. A width of the coolant flow path 250 on the inner side relative to the first part P1 is the same as the width W2 of the coolant flow path 250 in the second part P2 but may have a size different from that of the width W2. It is noted that the “width” of the coolant flow path 250 mentioned herein refers to a dimension of the coolant flow path 250 along a direction perpendicular to a direction in which the coolant flows in top view.

In such a configuration, a flow rate of the coolant flowing through the coolant flow path 251 becomes faster than a flow rate of the coolant flowing through other parts in the coolant flow path 250. As the flow rate increases, since a heat conductivity in the coolant flow path 251 increases, the first part P1 is more efficiently cooled down as compared with the second part P2. That is, with regard to the coolant flow path 250 of the present embodiment, as a result of setting the width of the coolant flow path 251 immediately below the edge E to be narrow, the cooling performance for the first part P1 becomes higher than the cooling performance for the second part P2.

With the cooling performance varied between the first part P1 and the second part P2, while the temperature increase in the outer circumferential part of the wafer W is sufficiently reduced, it is possible to avoid a situation where the member such as the focus ring arranged on the further outer side relative to the outer circumferential part of the wafer W is cooled down more than necessary. According to this, the in-plane temperature distribution of the wafer W during the process can be more uniform than before.

A second embodiment will be described. Hereinafter, an aspect different from the first embodiment will be mainly described, and descriptions on an aspect common to the first embodiment are not repeated as appropriate.

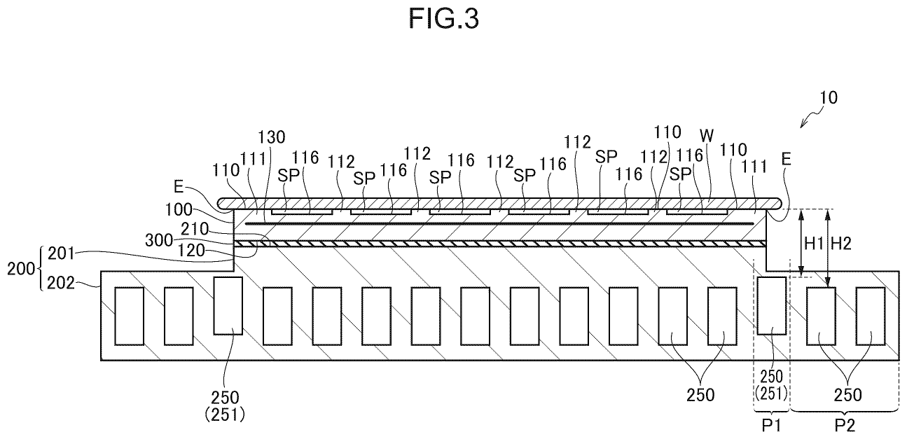

FIG. 3 is a cross sectional view illustrating a configuration of the electrostatic chuck 10 according to the present embodiment similarly as in FIG. 1. According to the present embodiment too, similarly as in the first embodiment, the coolant flow path 250 is formed inside the base plate 200, and a part (the coolant flow path 251) of the coolant flow path 250 is routed so as to pass through the first part P1 immediately below the edge E. The width of the coolant flow path 250 according to the present embodiment is set to be uniform throughout the entirety including the coolant flow path 251.

A distance along the direction perpendicular to the surface 110 serving as the placement surface that is a distance between the coolant flow path 250 and the surface 110 will also be hereinafter referred to as a “coolant distance”. The coolant distance is to be defined in each part of the coolant flow path 250 and can be regarded as an index representing a height position of the coolant flow path 250. As illustrated in FIG. 3, according to the present embodiment, the coolant flow path 250 is routed such that the coolant distance (H1) in the first part P1 becomes shorter than the coolant distance (H2) in the second part P2. In other words, the coolant flow path 250 is in a higher position in the first part P1 as compared with other parts, and the coolant flow path 250 is routed so as to pass through a position close to the surface 110, which serves as the placement surface. The coolant distance of the coolant flow path 250 in the part on the inner side relative to the first part P1 is the same as the coolant distance (H2) in the second part P2 but may be a distance different from the coolant distance (H2).

In such a configuration, a thermal resistance between the coolant flow path 251 and the surface 110 in the first part P1 becomes smaller than a thermal resistance between the coolant flow path 250 and the surface 110 in the second part P2. As a result, the first part P1 is more efficiently cooled down as compared with the second part P2. That is, with regard to the coolant flow path 250 of the present embodiment, as a result of setting the coolant distance immediately below the edge E to be small, the cooling performance for the first part P1 becomes higher than the cooling performance for the second part P2. With such a configuration too, an effect similar to that described in the first embodiment can be attained.

A third embodiment will be described. Hereinafter, an aspect different from the first embodiment will be mainly described, and descriptions on an aspect common to the first embodiment are not repeated as appropriate.

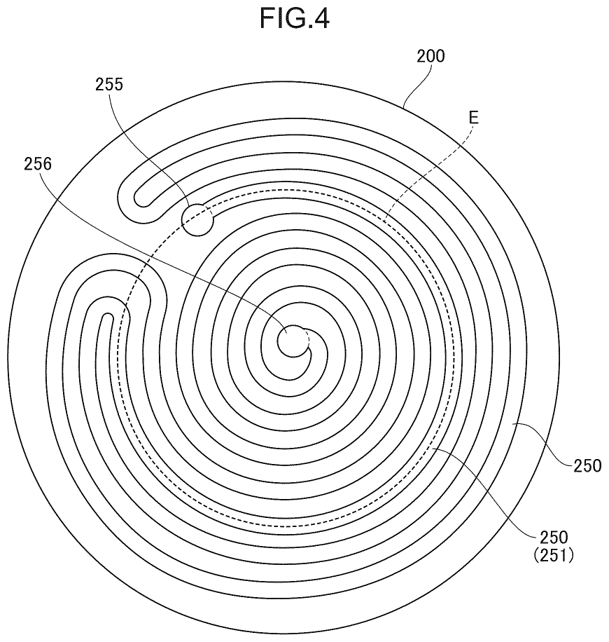

FIG. 4 illustrates a configuration of the coolant flow path 250 formed in the base plate 200 of the present embodiment in a manner similar to that of FIG. 2. According to the present embodiment too, similarly as in the first embodiment, the coolant flow path 250 is formed inside the base plate 200, and a part (the coolant flow path 251) of the coolant flow path 250 is routed so as to pass through the first part P1 immediately below the edge E. The width of the coolant flow path 250 according to the present embodiment is set to be uniform throughout the entirety including the coolant flow path 251. The coolant distance according to the present embodiment is also uniform throughout the entirety including the coolant flow path 251.

As illustrated in FIG. 4, according to the present embodiment, the opening 255 serving as the inlet for the coolant to the coolant flow path 250 is formed in a position overlapped with the edge E in top view. That is, an end on one side (inlet side) of the coolant flow path 250 is arranged in the position overlapped with the edge E in top view.

In top view, the coolant flow path 250 extends in an arc-like manner from the opening 255 along the edge E and is routed so as to pass through the first part P1. That is, a part extending in an arc-like manner from the opening 255 as described above serves as the coolant flow path 251 according to the present embodiment. As may be obvious from FIG. 4, the coolant supplied to the opening 255 passes through the coolant flow path 251 first immediately below the edge E to cool down the first part P1. Thereafter, the coolant passes through the second part P2 on the outer side relative to the edge E to cool down the second part P2. Furthermore, thereafter, the coolant passes through a part on the inner side relative to the edge E to cool down the above-described part. Eventually, the coolant is exhausted to the outside from the opening 256. While the coolant passes through the above-described route, the temperature of the coolant gradually increases.

Since the coolant at a low temperature passes through the first part P1 first, the first part P1 is cooled down with a relatively high efficiency. On the other hand, since the coolant with an increased temperature after having passed through the first part P1 passes through the second part P2, the second part P2 is cooled down with a relatively low efficiency. That is, with regard to the coolant flow path 250 of the present embodiment, as a result of a setting the end on the inlet side which is connected to the opening 255 to be arranged immediately below the edge E, the cooling performance for the first part P1 is higher than the cooling performance for the second part P2. With such a configuration too, an effect similar to that described in the first embodiment can be attained.

It is noted that it is sufficient when only the end on one side of the coolant flow path 250 is arranged in a position overlapped with the edge E in top view, but both ends may be arranged in positions overlapped with the edge E. That is, both the openings 255 and 256 may be arranged in positions immediately below the edge E. In such a configuration, even in both cases where any of the opening 255 or the opening 256 is used as the inlet for the coolant, the first part P1 can be cooled down with a high efficiency.

The configuration of the coolant flow path 250 to set the cooling performance for the first part P1 to be higher than the cooling performance for the second part P2 is not limited to the above-described example, and various other modes can be adopted. For example, a distance between both the mutually adjacent coolant flow paths 250 in top view, that is, an arrangement interval between the coolant flow paths 250 may be varied depending on locations. Specifically, the arrangement interval between the coolant flow paths 250 in the first part P1 may be set to be narrower than the arrangement interval between the coolant flow paths in the second part P2. In such a mode too, an effect similar to that described in each of the above-described embodiments can be attained.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be attracted is placed; and
a base plate which is joined to the dielectric substrate and which has formed therein a coolant flow path through which a coolant is able to flow, wherein
when viewed from a direction perpendicular to the placement surface,
the base plate includes
a first part serving as a part overlapped with an outer circumferential edge of the placement surface, and
a second part serving as a part on a further outer circumferential side relative to the first part,
the coolant flow path is formed in each of the first part and the second part, and
the coolant flow path is formed in a manner that a cooling performance for the first part is set to be higher than a cooling performance for the second part.

2. The electrostatic chuck according to claim 1, wherein
a width of the coolant flow path in the first part is narrower than a width of the coolant flow path in the second part.

3. The electrostatic chuck according to claim 1, wherein
when a distance between the coolant flow path and the placement surface that is a distance along the direction perpendicular to the placement surface is set as a coolant distance,
the coolant distance in the first part is shorter than the coolant distance in the second part.

4. The electrostatic chuck according to claim 1, wherein
when viewed from the direction perpendicular to the placement surface,
an end on at least one side of the coolant flow path is arranged in a position overlapped with the outer circumferential edge of the placement surface.
